(19) United States
(12) Patent Application Publication
(10) Pub. No.: US 2017/0221751 A1
(43) Pub. Date: Aug. 3, 2017

(54) HIGH SPEED EPITAXY SYSTEM AND METHODS

(71) Applicant: Applied Materials, Inc., Santa Clara, CA (US)

(72) Inventors: Brian H. BURROWS, San Jose, CA (US); Lance A. SCUDDER, Sunnyvale, CA (US); David K. CARLSON, San Jose, CA (US); Kashif MAQSOOD, San Francisco, CA (US)

(73) Assignee: Applied Materials, Inc., Santa Clara, CA (US)

(21) Appl. No.: 15/501,148

(22) PCT Filed: Aug. 21, 2015
(86) PCT No.: PCT/US2015/046380

§ 371 Date: Feb. 1, 2017

Related U.S. Application Data
(60) Provisional application No. 62/040,725, filed on Aug. 22, 2014.

(51) Int. Cl. H01L 21/687

(52) U.S. Cl. CPC H01L 21/68785; H01L 21/68721; H01L 21/68771

(57) ABSTRACT

A substrate carrier for an epitaxy chamber is described that has an elongated base member supporting two substrate supports in an angled relationship and a center substrate support between the two substrate supports. The center substrate support has one or more openings at which a substrate is positioned for processing, enabling both sides of the substrate to be processed concurrently.

### FIELD

Embodiments described herein relate to methods of manufacturing semiconductor substrates. More specifically, embodiments described herein relate to apparatus for performing high-speed epitaxy processes.

### BACKGROUND

In semiconductor processing, various processes are commonly used to form films that have functionality in a semiconductor device. Among those processes are certain types of deposition processes referred to as epitaxy. In an epitaxy process, a gas mixture is typically introduced in a chamber containing one or more substrates on which an epitaxial layer is to be formed. Process conditions are maintained to encourage the vapor to form a high quality material layer on the substrate. Epitaxy is generally favored when high quality and uniformity of a film deposited across the surface of a substrate are desired.

Eiptaxy is commonly performed in deposition chambers that accommodate one workpiece at a time. Such chambers are used to form epitaxial layers a few nanometers thick on semiconductor substrates for increasingly small logic devices. Forming such layers typically takes a few minutes and may yield dozens of devices for each substrate. Thus, for logic devices such processes are still nominally useful.

New semiconductor processes are being designed that use epitaxial layers that may be many microns thick. Such layers might take hours or days to grow using conventional epitaxy apparatus, as described above. Thus, there is a need for a high-speed epitaxy system and methods.

### SUMMARY

Embodiments described herein include a substrate support for an epitaxy chamber. The substrate support may have a first surface having a plurality of recesses; a second surface opposite the first surface and together with the first surface defining a first edge and a second edge, opposite the first edge, of the substrate support, and a third edge between the first and second edges, and a fourth edge opposite the third edge; an opening through each recess from the first surface to the second surface; a ledge within each recess around a periphery of each opening; and a notch in each of the first and second edges, and a tab extending from each of the first and second edges.

Other embodiments include a substrate carrier, comprising an elongated base member having a first groove and a second groove extending longitudinally along the base member; a first substrate support seated in the first groove of the base member, the first substrate support comprising a plurality of recesses in a planar distribution, the first substrate support having a first edge and a second edge opposite the first edge; a second substrate support seated in the second groove of the base member, the second substrate support comprising a plurality of recesses in a planar distribution facing the recesses of the first substrate support, the second substrate support having a first edge aligned with the first edge of the first substrate support and a second edge aligned with the second edge of the first substrate support; a first wedge coupled to the elongated base member and joining the corresponding first edges of the first and second substrate supports; a second wedge coupled to the elongated base member opposite the first wedge and joining the corresponding second edges of the first and second substrate supports; a lid that, together with the elongated base member, the first and second substrate supports, and the first and second wedges, encloses a processing volume; and a third substrate support disposed in the processing volume, the third substrate support comprising a first surface having a plurality of recesses, each recess having an opening; a second surface opposite the first surface and together with the first surface defining a first edge and a second edge, opposite the first edge, of the substrate support, and a third edge between the first and second edges, and a fourth edge opposite the third edge; a ledge within each recess around a periphery of each opening; and a notch in each of the first and second edges, and a tab extending from each of the first and second edges.

Other embodiments include a substrate carrier, comprising an elongated base member having a first groove and a second groove extending longitudinally along the base member, and a plurality of openings between the first groove and the second groove; a first substrate support seated in the first groove of the base member, the first substrate support comprising a plurality of recesses in a planar distribution, the first substrate support having a first edge and a second edge opposite the first edge; a second substrate support seated in the second groove of the base member, the second substrate support comprising a plurality of recesses in a planar distribution facing the first substrate support, the second substrate support having a first edge aligned with the first edge of the first substrate support and a second edge aligned with the second edge of the first substrate support; a first wedge coupled to the elongated base member and joining the corresponding first edges of the first and second substrate supports, the first wedge comprising a prop and a pin; a second wedge coupled to the elongated base member opposite the first wedge and joining the corresponding second edges of the first and second substrate supports; a lid that, together with the elongated base member, the first and substrate supports, and the first and second wedges, encloses a processing volume; a lock rotatably disposed on the pin of the first wedge; and a third substrate support disposed on the elongated base member between the first and second substrate supports, the third substrate support comprising a first surface having a plurality of recesses, each recess having an opening through the recess; a second surface opposite the first surface and together with the first surface defining a first edge and a second edge, opposite the first edge, of the third substrate support, and a third edge between the first and second edges, and a fourth edge opposite the third edge; a ledge within each recess around a periphery of each opening; and a notch in each of the first and second edges, and a tab extending from each of the first and second edges, wherein the tab has a groove that engages with the lock, and the tab is positioned to engage with the prop.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of a substrate carrier according to one embodiment.

FIG. 2A is an exploded perspective view of the substrate carrier of FIG. 1.

FIG. 2B is a perspective view of the substrate carrier of FIG. 1 from a direction opposite the view of FIG. 2A.

FIG. 2C is a detailed view portion of the substrate carrier of FIG. 1.

FIG. 2D is a perspective view of the substrate carrier of FIG. 1 in a processing chamber.

FIG. 3A is a perspective view of a substrate support used in the substrate carrier of FIG. 1, according to one embodiment.

FIG. 3B is a perspective view of the substrate support of FIG. 3A showing installation of a substrate.

FIG. 30 is a cross-sectional view of a portion of the substrate support of FIG. 3B, with substrate installed, according to one embodiment.

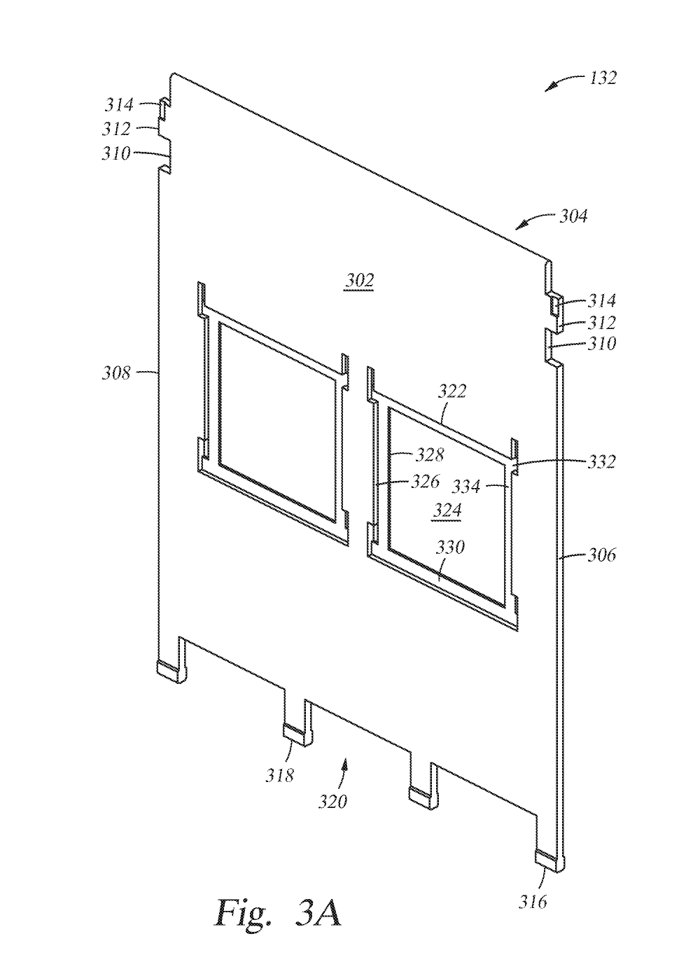

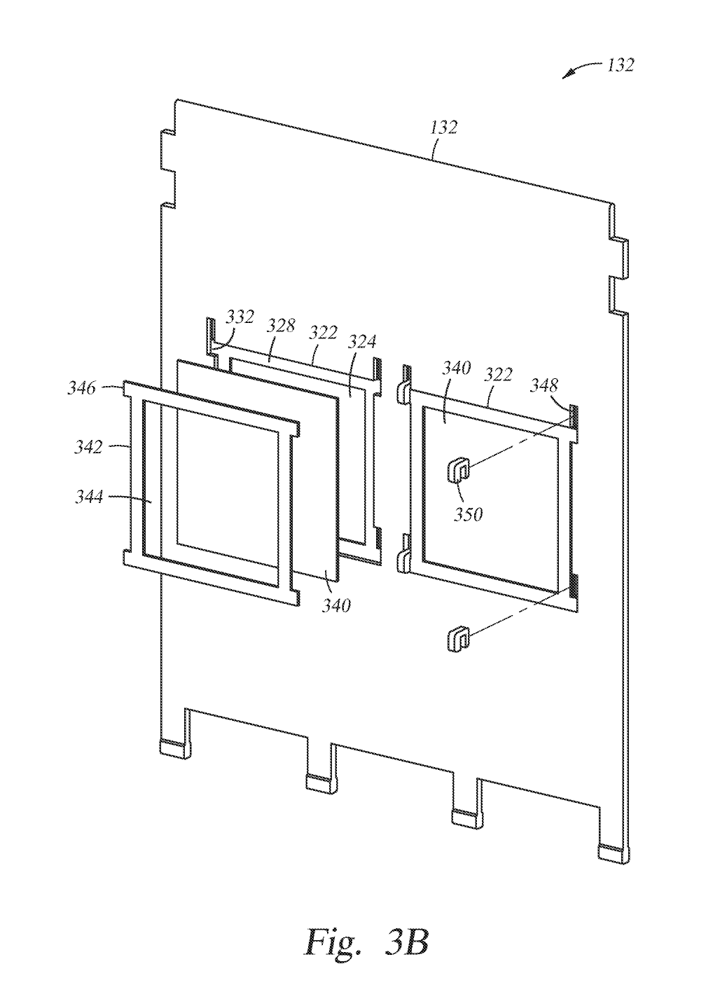

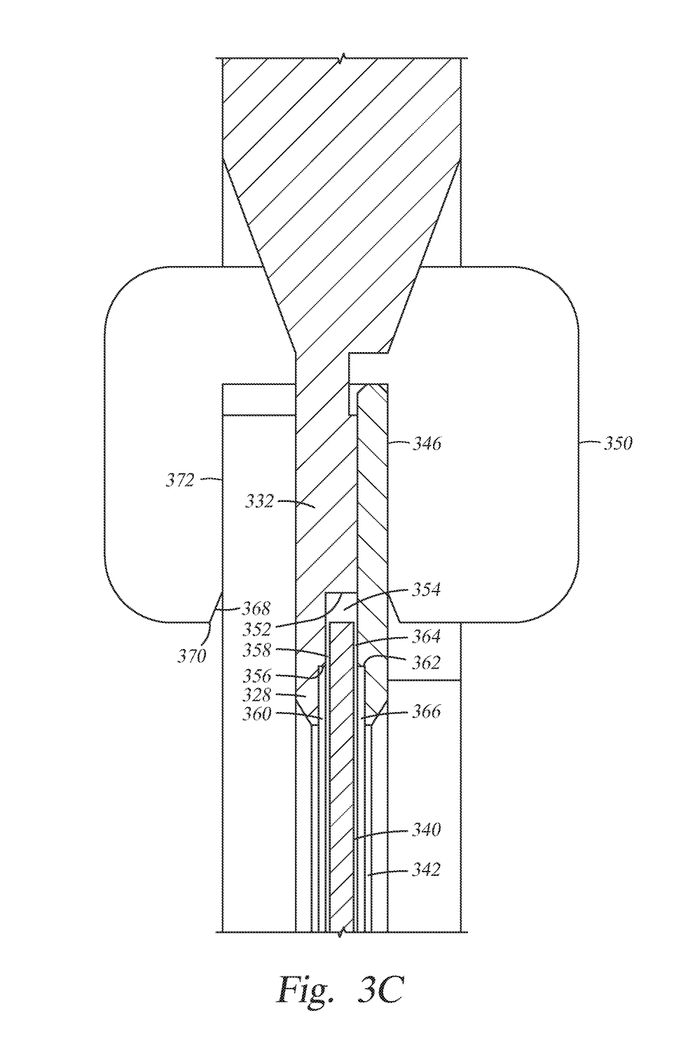

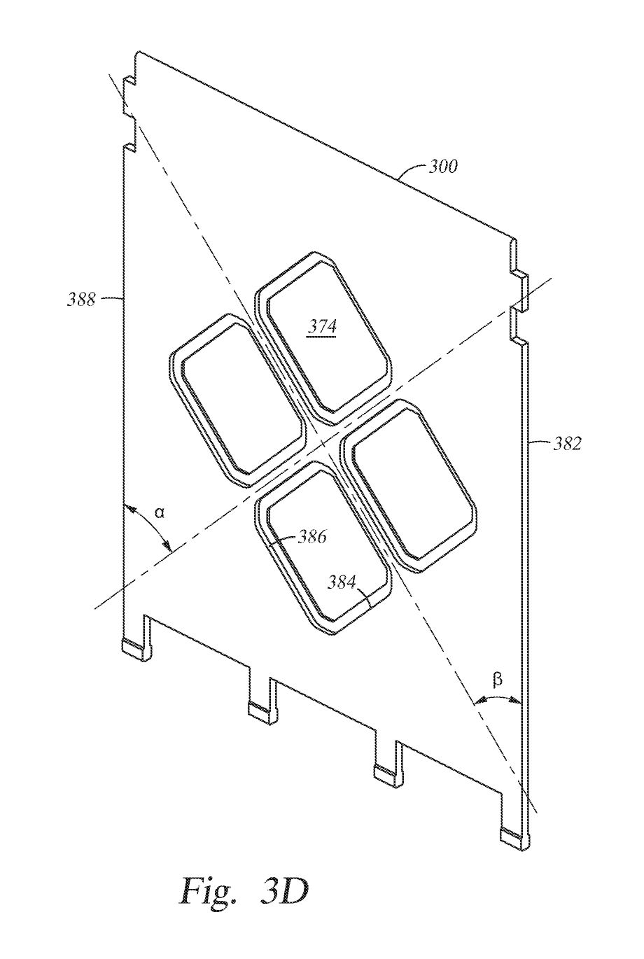

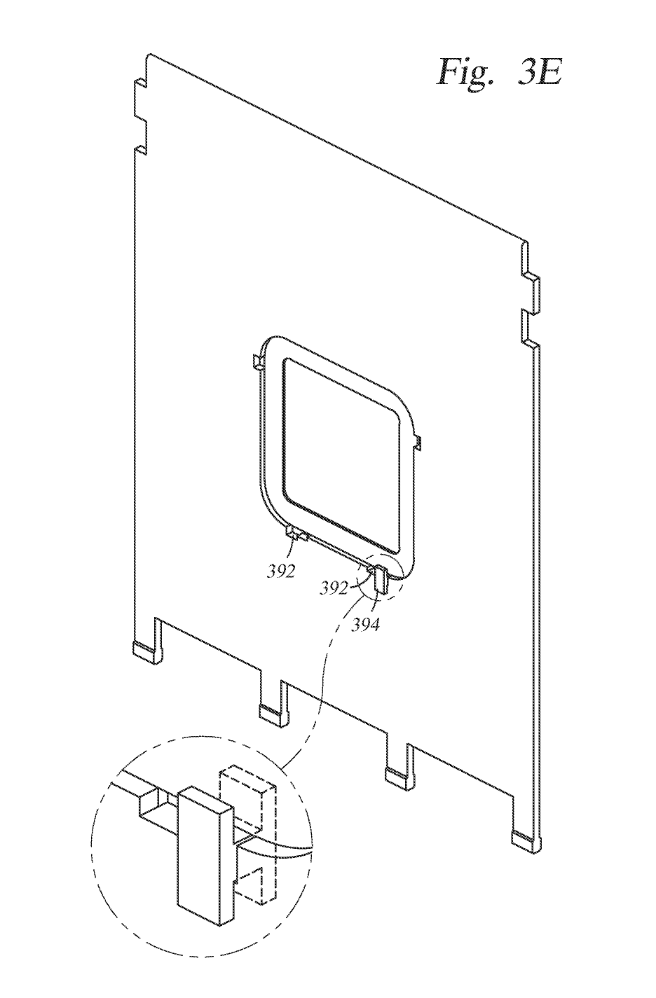

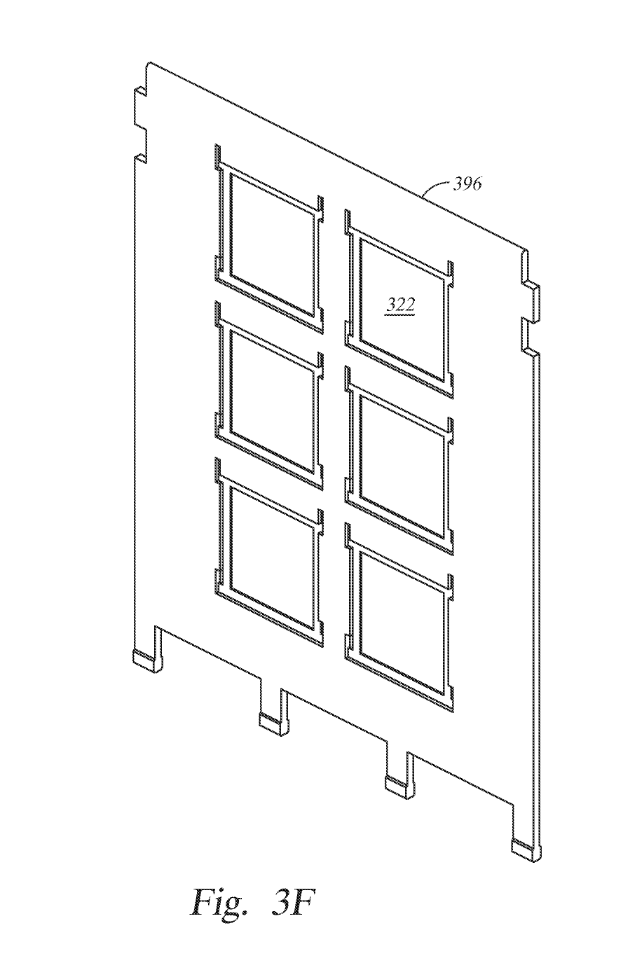

FIGS. 3D-3E are perspective view of substrate supports according to other embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to methods and apparatus for performing high-speed epitaxy. Such methods and apparatus may be useful for forming thick, high-quality epitaxial layers for devices such as crystalline silicon solar panels.

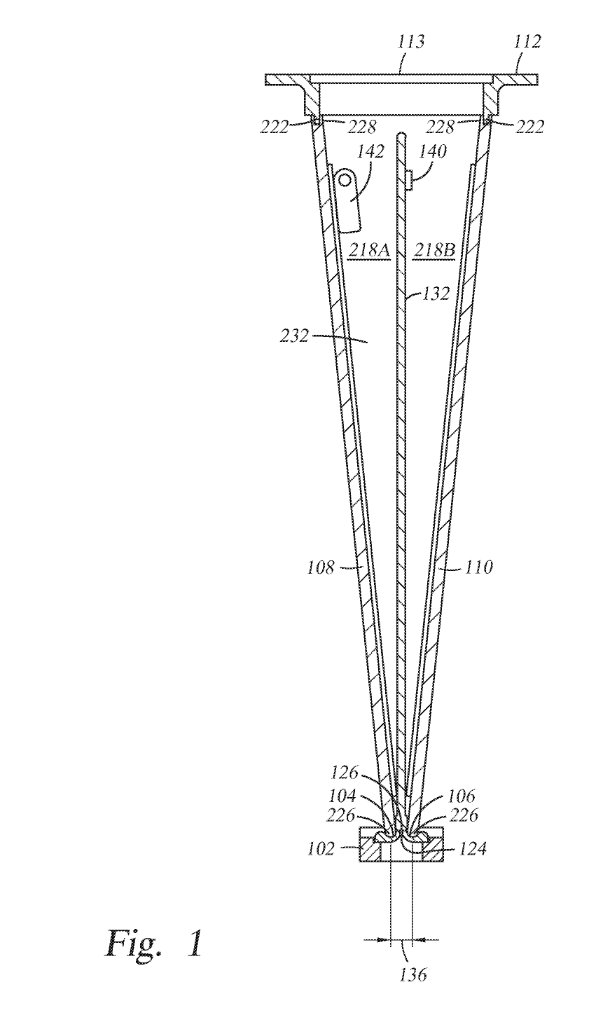

FIG. 1 is a cross-sectional view of a substrate carrier 100 according to one embodiment. The substrate carrier 100 has an elongated base member 102 that extends along a longitudinal direction near a central area of the substrate carrier 100. The elongated base member 102 has a first groove 104 extending along the base member 102 in the longitudinal direction and a second groove 106 extending along the elongated base member 102 in the longitudinal direction. A ridge 126 may extend along the elongated base member 102 between the first groove 104 and the second groove 106. A plurality of portals 124 may be formed in the ridge 126 to allow gas flow through the bottom of the substrate carrier 100 during processing.

A first substrate support 108 is seated in the first groove 104 and a second substrate support 110 is seated in the second groove 106. The first substrate support 108 is disposed at an angle to the second substrate support 110 by operation of a support tray 112 that holds the first and second substrate supports 108 and 110 in angled relationship. The support tray 112 may have an extension 222 that engages a top groove in each of the first substrate support 108 and the second substrate support 110.

A third substrate support 132 is disposed between the first substrate support 108 and the second substrate support 110. The third substrate support 132 holds one or more substrates in a processing orientation between the first substrate support 108 and the second substrate support 110, so that two opposing surfaces of the one or more substrates may be exposed to a processing environment between the first substrate support 108 and the second substrate support 110, enabling processing of both major surfaces of a substrate concurrently in the substrate carrier 100.

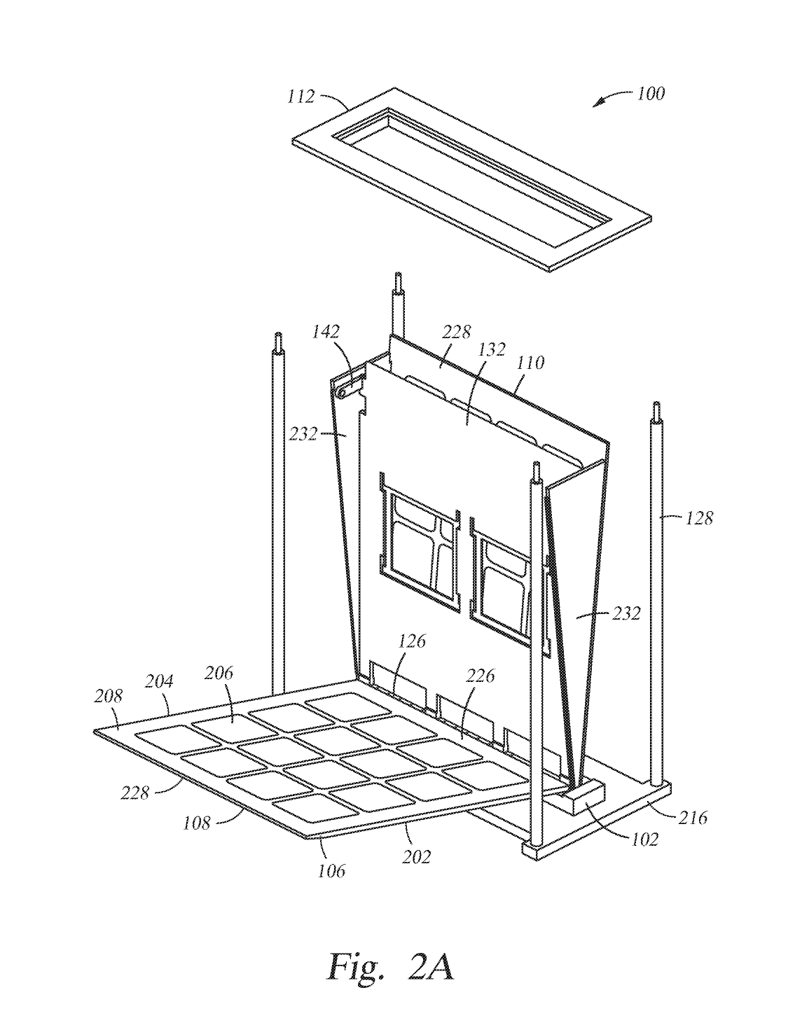

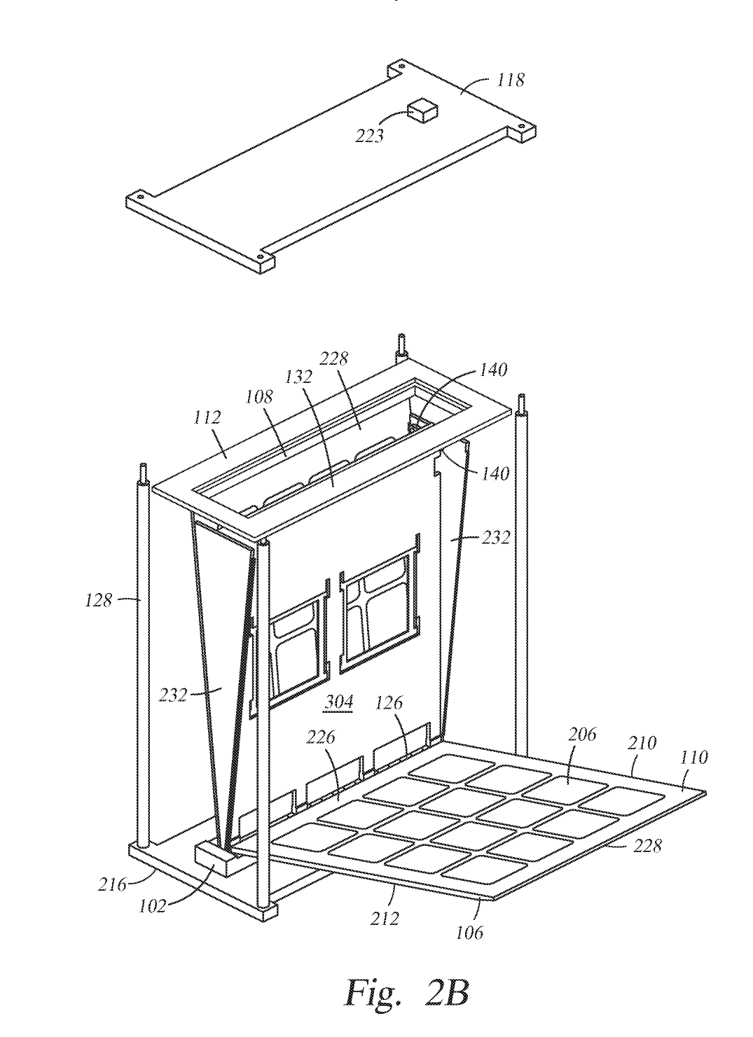

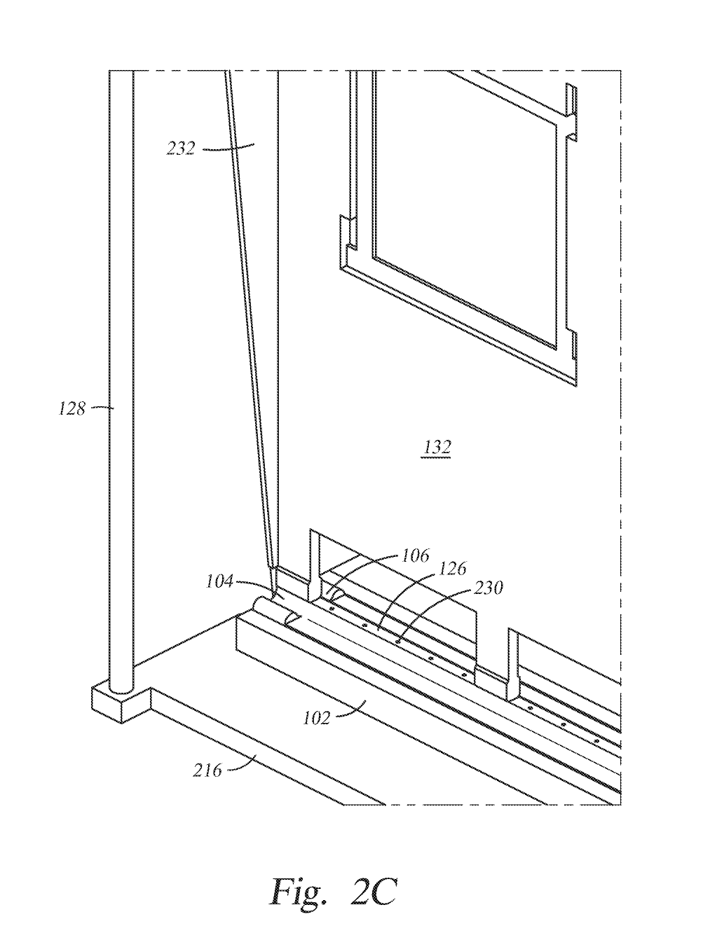

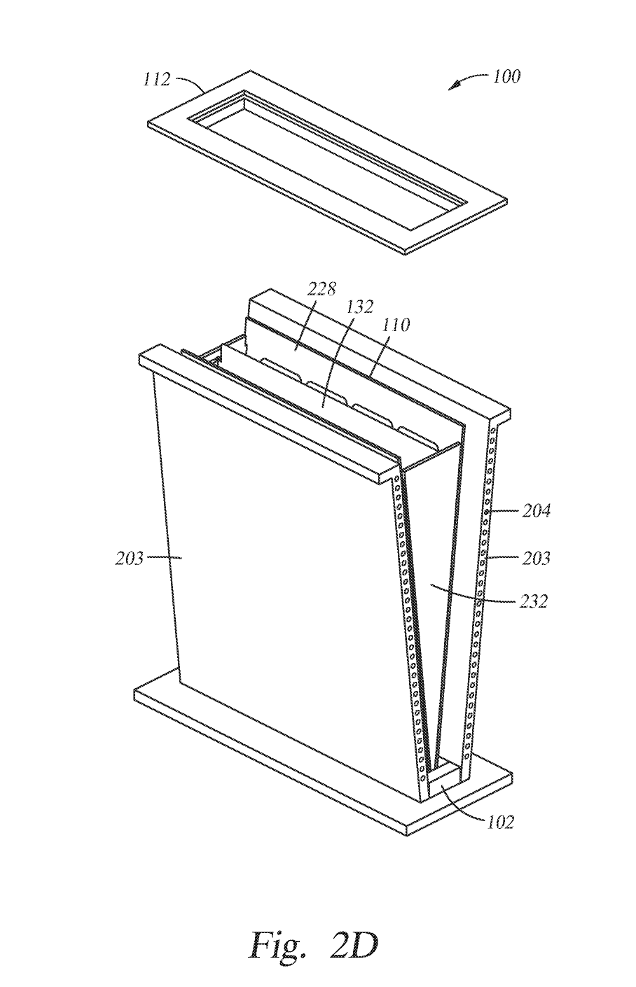

FIG. 2A is an exploded perspective view of the substrate carrier 100. The substrate carrier 100 is shown in FIG. 2A in an unloading configuration, with the support tray 112 removed. The first substrate support 108 is shown in an open configuration permitting access to load and unload substrates. The second substrate support 110 is still in a closed configuration.

The first substrate support 108 has a plurality of recesses 206 in a planar distribution across a surface of the first substrate support 108 for holding substrates. The recesses 206 are typically distributed across a surface 208 of the first substrate support 108 that faces the third substrate support 132 when the first substrate support 108 is in a closed configuration. The second substrate support 110 has a similar arrangement of heat sources, which may be radiant or resistive.

The first substrate support 108 has a first edge 202 and a second edge 204 opposite the first edge. FIG. 2B is a perspective view of the substrate carrier 100 from a direction opposite the view of FIG. 2A. The second substrate support 110 is shown in an open configuration in FIG. 2A. The second substrate support 110 also has a first edge 210 and a second edge 212. As noted above, the second substrate support 110 has a similar arrangement of recesses 206.

A first wedge 232 is disposed on the elongated base member 102 at a first end 216 thereof. A second wedge 232 is disposed on the elongated base member 102 at a second end 216 thereof. The elongated base member 102, the first substrate support 108, the second substrate support 110, the first wedge 232, the second wedge 232, and the support tray 112 together define and enclose a processing volume 218 (FIG. 1), which is divided into two processing regions by the third substrate support 132. The first wedge 232 couples together the first edge 202 of the first substrate support 108 and the first edge 210 of the second substrate support 110. The second wedge 232 couples together the second edge 204 of the first substrate support 108 and the second edge 212 of the second substrate support 110. The first edge 202 of the first substrate support 108 is thus aligned with the first edge 210 of the second substrate support 110, and the second edge 204 of the first substrate support 108 is aligned with the second edge 212 of the second substrate support 110.

Each of the first substrate support 108 and the second substrate support 110 has a third edge 226, the third edge 226 of the first substrate support 108 visible in FIG. 2A and the third edge 226 of the second substrate support 110 visible in FIG. 2B. The third edge 226 of each of the first and second substrate supports 108 and 110 are also visible in FIG. 1. The third edge 226 of the first substrate support 108 is seated in the first groove 104 of the elongated base member 102, and the third edge 226 of the second substrate support 110 is seated in the second groove 106 of the elongated base member 102. A fourth edge 228 of each of the first and second substrate supports 108 and 110 is located opposite the third edge 226. The fourth edge 228 of each substrate support 108, 110, has a groove, which may be a top groove, into which the extension 222 may fit.

FIG. 2C is a detailed view of a portion of the substrate carrier 100 of FIG. 1. The view of FIG. 20 highlights a portion of the third substrate support 132 where the third substrate support 132 rests on the ridge 126 of the base member 102 between the first groove 104 and the second groove 106. The substrate supports 108 and 110 are removed for clarity in FIG. 20. A plurality of gas outlet portals 230 are formed in the ridge 126 for exhausting gas from the processing volume 218. When the substrate supports 108 and 110 are installed in the substrate carrier 100, the processing volume 218 has a V-shape resulting from the angled position of the substrate supports 108 and 110. The V-shape ensures the processing volume 218 has a linearly declining volume in the direction of gas flow to compensate for gas depletion from the inlet to the outlet of the processing volume 218. An exhaust plenum (not shown) may be coupled to the base member 102 opposite the gas outlet portals 230 to provide a source of vacuum for evacuating gas from the substrate carrier 100, when the substrate carrier 100 is positioned in a processing chamber.

Referring again to FIG. 1, the extension 222 of the support tray 112 may extend into the top groove in the fourth edge 228 of each of the first and second substrate supports 108 and 110, so that the support tray 112 is in a supporting relation to the first and second substrate supports 108 and 110, as noted above. A portion of the extension 222 that contacts the first substrate support 108 is separated from an opposite portion of the extension 222 that contacts the second substrate support 110 by a first distance 134. The first groove 104 is separated from the second groove 106 by a second distance 136. The first distance 134 may be larger than the second distance 136, such that the first substrate support 108 and the second substrate support 110 are maintained in an angled relationship.

Precursor gases may be provided to the substrate carrier 100 by coupling a gas plenum to the support tray 112. The gases flow through the support tray 112 into the processing volume 218. A gas distributor may be used with the support tray 112 to provide uniform gas flow into the processing volume 218, if desired.

The third substrate support 132 is disposed in the processing volume 218 and divides the processing volume 218 into two parts 218A and 2188. The third substrate support 132 may bifurcate the processing volume 218 into two parts 218A and 2188 having the same volume. A prop 140 and a lock 142 maintain the third substrate support 132 in an upright position inside the processing volume 218. The lock 142 is shown in FIG. 1 disengaged from the prop 140. In FIG. 2A, the lock 142 is shown engaged with the third substrate support 132 in a supporting relation. In FIG. 2B, a portion of the prop 140 is visible. The prop 140 engages an edge of the third substrate support 132, while the lock 142 is rotated into a supporting position to hold the third substrate support 132 against the prop 140.

FIG. 2D is a perspective view of the substrate carrier 100 in a processing configuration inside a processing chamber. The processing chamber has two walls 203 that are shaped in a way that closely couples the walls 203 to the substrate supports, such as the substrate support 110, of the substrate carrier 100. The walls 203 include conduits 204 for supplying heat to the processing volume 218.

FIG. 3A is a perspective view of the third substrate support 132 of FIG. 1, according to one embodiment. The third substrate support 132 has a first surface 302 and a second surface 304 (visible in the view of FIG. 2B) that together define a first edge 306 and a second edge 308 opposite the first edge 306. Each of the first edge 306 and the second edge 308 has a notch 310 and a tab 312. The tab 312 engages the prop 140 (FIGS. 1, 2B) to maintain the third substrate support 132 in an upright position inside the processing volume 218. Each tab 312 has a groove 314 that engages with the lock 142 (FIG. 1, 2B). The lock 142 deploys in the groove 314 to secure the third substrate support 132 against the prop 140. During loading and loading of the third substrate support 132, the notch 310 in each of the first and second edges 306 and 308 allows the third substrate support 132 to be rotated from its upright processing position past the prop 140, with the notch 310 providing clearance past the prop 140, to an inclined loading and unloading position, and vice versa.

A third edge 316 of the third substrate support 132 between the first edge 306 and the second edge 308 has a plurality of posts 318, each pair of posts 318 being separated by a cutout 320. When the third substrate support 132 is in a processing position in the processing volume 218, the posts 318 rest on the ridge 126, and the cutouts 320 provide clearance for gas to flow from the processing volume 218 to the gas outlet portals 230 (FIG. 2C).

A plurality of recesses 322 are formed in the third substrate support 132. Each recess has an opening 324 through the third substrate support 132 from the first surface 302 to the second surface 304. Each recess 322 is defined by an outer wall 326, and has a ledge 328 that extends from the outer wall 326 inward to cover a peripheral portion 330 of the opening 324. Each ledge 328 is disposed around the periphery of an opening 324, and has a clamp area 332 that extends away from an inner radius 334 of the ledge 328.

FIG. 3B is a perspective view of the third substrate support 132 showing installation of a substrate 340 in each of the recesses 322. The substrate 340 fits in the recess 322 and engages the ledge 328. The ledge 320 supports the substrate 340 in a processing position with the opening 324 exposing the surface of the substrate 340 facing the ledge 328 to the portion of the processing volume 218 on the opposite side of the third substrate support 132, while the surface of the substrate 340 facing away from the ledge 328 is exposed to the portion of the processing volume 218 on the same side of the third substrate support 132. A frame 342 fits in each recess 328, and an opening 344 of the frame 342 aligns with the opening 324 of each recess 328. Each frame 342 has a clamp tab 346 that mates with the clamp area 332. Each recess 322 has at least one clamp area 332, and each frame 342 has at least one corresponding clamp tab 346. Any convenient number of clamp areas 332 and clamp tabs 346 may be used, and each recess 322 may have the same number of clamp areas 332 and clamp tabs 346, or more clamp areas 332 than clamp tabs 346.

A clamp slot 348 may be provided through the third substrate support 132 adjacent to each clamp area 332. A clamp 350 may be inserted into the clamp slot 348 and clamped over the clamp tab 346 of the frame 342 and the clamp area 332 of the recess 322 to secure the frame 342 to the third substrate support 132, and secure the substrate 340 between the frame 342 and the ledge 328. To remove a substrate 340 from the substrate support 342, the clamp 350 may be removed from the clamp slot 348, and the frame 342 may be removed.

FIG. 3C is a detailed cross-sectional view of a portion of the third substrate support 132 according to one embodiment. A clamp 350 is deployed through the clamp slot (FIG. 3B), so a portion of the clamp 350 appears on either side of the third substrate support 132. The clamp 350 is deployed over the clamp tab 346 of the frame 342. The clamp area 332 has a raised contact surface 352 for contacting the clamp tab 346 of the frame 342. The ledge 328, raised portion 352, and clamp tab 346 define a capture space 354 that receives a portion of the substrate 340. The ledge 328 may have a stepped region 356 the divides the ledge 328 into a proximal portion 358 and a distal portion 360. The clamp tab 346 may also have a stepped region 362 that divides the clamp tab 346 into a proximal portion 364 and a distal portion 366. In this way, contact between the substrate 340 and the third substrate support 132 is confined to the capture space 354, and therefore minimized. The clamp 350 may have a bevel 368 at an end 370 of a contact surface 372 of the clamp 350 to facilitate engagement of the clamp 350 with the clamp tab 346.

The recesses 322 shown in FIGS. 2A-3C are aligned with the edges of the third substrate support 132. The recesses 322 are arranged in the third substrate support 132 such that any axes of symmetry form right angles with the edges of the substrate support. FIG. 3D is a perspective view of a substrate support 300 according to another embodiment. The substrate support 300 is the same as the third substrate support 132 in most respects. In FIG. 3D, recesses 374 are arranged such that axes of symmetry 376 and 378 form acute angles α and β with respect to edges 380 and 382 of the substrate support 300. The recesses 374 each have a ledge 388, and the recesses 374 are defined by an outer wall 384 that may have a groove 386 for receiving a substrate. The substrate is placed on the ledge 388 and is then slid into the groove 386 to secure the substrate to the substrate support 300. It should be noted that the substrate support 300 may be used for square or rectangular shaped substrates, or for circular substrates.

FIG. 3E is a perspective view of a substrate support 390 according to another embodiment. The substrate support 390 is the same as the substrate supports 132 and 300 in most respects. The substrate support 390 has a sliding clamp mechanism 392 with non-removable clamps 394. One recess is shown in the substrate support 390, but any number may be used, as in FIGS. 3A-3D. FIG. 3F is a perspective view of a substrate support 396 with six of the recesses 322 for substrates.

While the foregoing is directed to embodiments of the invention, other and further embodiments of the invention may be devised without departing from the basic scope thereof.

What is claimed is:

1. A substrate support for a processing chamber, the substrate support comprising:
a first surface having a plurality of recesses;
a second surface opposite the first surface and having a plurality of openings, each opening located within one of the plurality of recesses in the first surface and defining a first edge having a notch, a second edge having a notch opposite the first edge, a third edge between the first and second edges, and a fourth edge opposite the third edge;
a ledge within each recess around a periphery of each opening; and
a tab extending from each of the first and second edges.

2. The substrate support of claim 1, wherein the third edge comprises a plurality of tabs, each pair of adjacent tabs in the third edge separated by a cutout, and the tabs and notches of the first and second edges are nearer the fourth edge than the third edge.

3. The substrate support of claim 2, wherein the notches in the first and second edges are aligned and the tabs of the first and second edges are aligned.

4. The substrate support of claim 1, wherein each recess defines an outer wall enclosing the recess, and the ledge extends from the outer wall, and further comprising a groove in the outer wall extending at least partway around a circumference of each recess.

5. The substrate support of claim 1, wherein each ledge has a clamp area that extends away from an inner radius of the ledge.

6. The substrate support of claim 5, further comprising a clamp slot adjacent to each clamp area.

7. The substrate support of claim 6, further comprising a frame that fits each recess, wherein the frame has an opening that aligns with the opening of the recess, and a clamp tab that mates with each clamp area of each ledge.

8. The substrate support of claim 4, wherein a symmetry axis of the plurality of recesses forms an acute angle with respect to a line perpendicular to the first edge.

9. A substrate carrier, comprising:
an elongated base member having a first groove and a second groove extending longitudinally along the base member;
a first substrate support seated in the first groove of the base member, the first substrate support comprising a plurality of recesses in a planar distribution, the first substrate support having a first edge and a second edge opposite the first edge;
a second substrate support seated in the second groove of the base member, the second substrate support comprising a plurality of recesses in a planar distribution facing the recesses of the first substrate support, the second substrate support having a first edge aligned with the first edge of the first substrate support and a second edge aligned with the second edge of the first substrate support;
a first wedge coupled to the elongated base member and joining the corresponding first edges of the first and second substrate supports;
a second wedge coupled to the elongated base member opposite the first wedge and joining the corresponding second edges of the first and second substrate supports;
a lid that, together with the elongated base member, the first and second substrate supports, and the first and second wedges, encloses a processing volume; and
a third substrate support disposed in the processing volume, the third substrate support comprising:
a first surface having a plurality of recesses, each recess having an opening;
a second surface opposite the first surface and together with the first surface defining a first edge and a second edge, opposite the first edge, of the substrate support, and a third edge between the first and second edges, and a fourth edge opposite the third edge;
a ledge within each recess around a periphery of each opening; and
a notch in each of the first and second edges, and a tab extending from each of the first and second edges.

10. The substrate carrier of claim 9, wherein the third edge comprises a plurality of tabs, each pair of adjacent tabs in the third edge separated by a cutout, and the tabs and notches of the first and second edges are nearer the fourth edge than the third edge.

11. The substrate carrier of claim 10, wherein the elongated base member further comprises a ridge extending along the longitudinal axis of the base member, and each of the plurality of tabs of the third edge engages with the ridge.

12. The substrate carrier of claim 11, wherein the lid comprises a support tray in a supporting relation to the fourth edge of each of the first and second heat panels.

13. The substrate carrier of claim 12, wherein the elongated base member has a plurality of openings.

14. The substrate carrier of claim 13, wherein the first wedge comprises a prop and a pin.

15. The substrate carrier of claim 14, further comprising a lock rotatably disposed on the pin.

16. A substrate carrier, comprising:
an elongated base member having a first groove and a second groove extending longitudinally along the base member, and a plurality of openings between the first groove and the second groove;
a first substrate support seated in the first groove of the base member, the first substrate support comprising a plurality of recesses in a planar distribution, the first substrate support having a first edge and a second edge opposite the first edge;
a second substrate support seated in the second groove of the base member, the second substrate support comprising a plurality of recesses in a planar distribution facing the first substrate support, the second substrate support having a first edge aligned with the first edge of the first substrate support and a second edge aligned with the second edge of the first substrate support;
a first wedge coupled to the elongated base member and joining the corresponding first edges of the first and second substrate supports, the first wedge comprising a prop and a pin;
a second wedge coupled to the elongated base member opposite the first wedge and joining the corresponding second edges of the first and second substrate supports;
a lid that, together with the elongated base member, the first and substrate supports, and the first and second wedges, encloses a processing volume;
a lock rotatably disposed on the pin of the first wedge; and
a third substrate support disposed on the elongated base member between the first and second substrate supports, the third substrate support comprising:
a first surface having a plurality of recesses, each recess having an opening through the recess;
a second surface opposite the first surface and together with the first surface defining a first edge and a second edge, opposite the first edge, of the third substrate support, and a third edge between the first and second edges, and a fourth edge opposite the third edge;
a ledge within each recess around a periphery of each opening; and
a notch in each of the first and second edges, and a tab extending from each of the first and second edges, wherein the tab has a groove that engages with the lock, and the tab is positioned to engage with the prop.
